(19) United States
(12) Patent Application Publication
(10) Pub. No.: US 2009/0139568 A1
(43) Pub. Date: Jun. 4, 2009

(54) Crystalline Solar Cell Metallization Methods

(75) Inventors: Timothy W. Weidman, Sunnyvale, CA (US); Michael P. Stewart, Mountain View, CA (US); Kapila P. Wijekoon, Palo Alto, CA (US); Rohit Mishra, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 12/273,975

(22) Filed: Nov. 19, 2008

Related U.S. Application Data
(60) Provisional application No. 61/003,754, filed on Nov. 19, 2007.

(51) Int. Cl. H01L 31/00; H01L 21/02; H01L 31/18

(52) U.S. Cl. 136/256; 438/98; 257/E21.002

(57) ABSTRACT

Embodiments of the invention contemplate formation of a low cost solar cell using novel methods and apparatus to form a metal contact structure. The method generally uses a conductive contact layer that enables formation of a good electrical contact to the solar cell device. In one case, the contact layer is a nickel containing layer. Various deposition techniques may be used to form the metal contact structure.

### CROSS-REFERENCE TO RELATED APPLICATIONS

This application claims the benefit of United States Provisional Patent Application Ser. No. 61/003,754 [Attorney Docket # APPM 12974L], filed Nov. 19, 2007, which is herein incorporated by reference.

### BACKGROUND OF THE INVENTION

1. Field of the Invention

Embodiments of the invention generally relate to the fabrication of photovoltaic cells.

2. Description of the Related Art

Solar cells are photovoltaic devices that convert sunlight directly into electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost to form solar cells.

Various approaches enable fabricating current carrying metal lines, or conductors, of the solar cells. However, there are several issues with these prior manufacturing methods. For example, the conductors often suffer from defects or are made in complicated multistep processes that add to costs required to complete the solar cells. Traditionally, the current carrying metal lines, or conductors, in solar cell devices are fabricated using a screen printing process in which a silver-containing paste is deposited in a desired pattern on a substrate surface and then annealed. However, there are several issues with this manufacturing method. First, the conductive paths (e.g., “fingers”), when formed by the screen printing process, may be discontinuous since the fingers formed using a metal paste do not always agglomerate into a continuous interconnecting line during the high temperature annealing process. Second, porosity present in the fingers formed during the agglomeration process results in greater resistive losses. Third, electrical shunts may be formed by diffusion of the metal (e.g., silver) from the contact into the p-type base region or on the surface of the substrate backside. Shunts on the substrate backside are caused by poor definition of backside contacts such as waviness, and/or metal residue. Fourth, due to the relatively thin substrate thicknesses commonly used in solar cell applications, such as 200 micrometers and less, the act of screen printing the metal paste on the substrate surface can cause physical damage to the substrate. Fifth, the screen printing processes typically require some amount of over-burden that leads to material that is wasted, or an amount that is in excess of what is required to metalize the substrate, thus needlessly increasing the cost of the solar cell. Lastly, silver-based paste is a relatively expensive material for forming conductive components of a solar cell.

Therefore, there exists a need for improved methods and apparatus to form a conductive material on a surface of a substrate to form, for example, a solar cell.

### SUMMARY OF THE INVENTION

A method, in one embodiment, of forming a solar cell device includes disposing a photoresist layer on a surface of a solar cell substrate. Exposing and developing the photoresist layer using a light source and a developing chemistry forms a desired pattern in the photoresist layer. Further, use of an etching chemistry exposes a silicon containing region of the substrate within the pattern. An electroless deposition process deposits a nickel containing layer on the silicon containing region while the photoresist layer with the desired pattern remains on the surface of the substrate. The method further includes depositing a fill layer on the nickel containing layer.

For one embodiment, another method enables forming a solar cell device. The method includes disposing a solar cell substrate on a carrier, applying a photoresist onto an antireflective coating of the substrate, patterning the photoresist to create channels in the photoresist, removing the antireflective coating within the channels, and depositing a nickel containing layer within the channels of the photoresist and onto the substrate where the antireflective coating is removed. The photoresist may extend to a surface of the carrier surrounding the substrate to seal the substrate between the carrier and the photoresist.

Embodiments of the invention further provide a method of forming a solar cell device, comprising removing a portion of an ARC layer from a surface of a solar cell substrate, depositing a contact layer on the silicon containing region using an electroless deposition process, and connecting a bus wire to the contact layer.

Embodiments of the invention further provide a method of forming a solar cell device, comprising disposing a metal containing ink on a region of a solar cell substrate, heating the metal containing ink to one or more temperatures to cause the chemicals in the ink to remove a material from the surface of the solar cell substrate and to form a silicide with a material on the surface of the solar cell substrate, and connecting a bus wire to the formed silicide layer.

Embodiments of the invention further provide a method of forming a solar cell device, comprising disposing a doping material on a region of a solar cell substrate, heating the doping material to a desired temperature to cause a dopant in the doping material to react with the a material in the substrate surface, depositing a contact layer on the material in the reacted region using an electroless deposition process, and connecting a bus wire to the contact layer.

Embodiments of the invention further provide a method of forming a solar cell device on a solar cell substrate, comprising disposing a photoresist layer on a surface of a substrate and a surface of a substrate carrier to substantially enclose the substrate within a space formed between the resist layer and the substrate carrier, patterning the photoresist layer disposed on the surface of the substrate to expose one or more regions of the surface of the substrate, removing material from the one or more regions of the surface so that a silicon containing material is exposed, electrolessly depositing a contact layer on the exposed silicon containing material, wherein the substrate remains disposed within the space during the patterning, the removing material, and the electrolessly depositing processes, and depositing a fill layer on the contact layer.

Embodiments of the invention further provide a method of forming a solar cell device, comprising applying a composite assembly onto a surface of the solar cell substrate, wherein the composite assembly comprises a light sensitive material layer that is positioned over the surface of the substrate, patterning the light sensitive material layer to form channels in the light sensitive material to expose one or more regions of the surface, removing material from the one or more regions of the surface so that a silicon containing material is exposed, depositing a contact layer on the exposed silicon containing material to form an array of metal lines and two or more substantially transversely oriented buss bars on the front surface of a solar cell substrate, and cutting a plurality of buss wires 132 to one or more desired lengths and bonding each of the plurality of bus wires to portion of the deposited contact layer.

Embodiments of the invention further provide an assembly for forming a solar cell device, comprising a carrier having a surface, a composite assembly comprising a light sensitive material layer, and a solar cell substrate disposed between the surface of the carrier and the composite assembly, wherein the solar cell substrate is sealably enclosed between the carrier and the composite assembly.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. The patent or application file contains at least one drawing executed in color. Copies of this patent or patent application publication with color drawing(s) will be provided by the Office upon request and payment of the necessary fee.

FIG. 1A illustrates a cross-sectional side view of a solar cell prior to forming conductors in a pattern on a front side of the solar cell, according to embodiments of the invention.

FIG. 1B illustrates a cross-sectional side view of the solar cell shown in FIG. 1A after partial removal of an antireflective coating and forming of the conductors where the coating is removed, according to embodiments of the invention.

FIG. 1C illustrates an isometric view of the solar cell upon completion with a front side metallization interconnect pattern, according to embodiments of the invention.

FIGS. 1D-1E illustrate a protective support upon which a backside of the solar cell shown in FIG. 1A is disposed during manufacturing processes, according to embodiments of the invention.

FIGS. 2A-2I illustrate schematic cross-sectional views of a solar cell during different stages in a sequence for forming conductors on a face side of the solar cell, according to one embodiment of the invention.

FIGS. 3A and 3B illustrate schematic cross-sectional views of a solar cell during different stages of a process in which a resist is removed prior to an anneal and then further deposition of conductors on a face side of the solar cell, according to one embodiment of the invention.

FIGS. 4A and 4B illustrate schematic cross-sectional views of a solar cell during different stages of a process in which light is used in the sequence depicted by FIGS. 2A-2I to assist in deposition of the conductors, according to one embodiment of the invention.

FIG. 5 illustrates a flow chart of methods to create a solar cell with process sequences corresponding to the stages depicted in FIGS. 2A-4B, according to embodiments of the invention.

FIG. 6 illustrates a flow chart of methods to metalize a solar cell according to embodiments of the invention.

FIGS. 7A-7D illustrate schematic cross-sectional views of a solar cell during different stages in a sequence according to one embodiment of the invention.

FIGS. 8A-8D illustrate schematic cross-sectional views of a solar cell during different stages in a sequence according to one embodiment of the invention.

FIG. 9 illustrates a flow chart of methods to metalize a solar cell according to embodiments of the invention.

FIG. 10 is a graph illustrating the increase in efficiency of a solar cell versus the number of current carrying bus bars according to embodiments of the invention.

FIG. 11 illustrates a plan view of a metalized structure formed on the front side of a solar cell substrate according to embodiments of the invention.

For clarity, identical reference numerals have been used, where applicable, to designate identical elements that are common between figures. It is contemplated that features of one embodiment may be incorporated in other embodiments without further recitation.

### DETAILED DESCRIPTION

Embodiments of the invention contemplate formation of a low cost solar cell using novel methods and apparatus to form a metal contact structure. In one embodiment, the methods include the use of a photoresist material that is used to define where the metal contact structure is to be located on a surface of a solar cell substrate. In another embodiment, the methods include the use of various etching and patterning processes that are used to define where the metal contact structure is to be located on a surface of a solar cell substrate. The method generally uses a conductive contact layer that enables formation of a good electrical contact to the solar cell device. In one case, the contact layer is a nickel, or silver, containing layer that is disposed onto exposed areas of the substrate surface prior to removal of a patterned photoresist material. The contact layer may also be used as a seed layer that is used to form additional conducting and/or protective capping layers that will form part of the metal contact structure. Various techniques may be used to form the metal contact structure. Solar cell substrates that may benefit from the invention include flexible substrates that may have an active region that contains organic material, single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallilium indium phosphide (GaInP₂), as well as heterojunction cells, such as GaInP/GaAs/Ge or ZnSe/GaAs/Ge substrates, that are used to convert sunlight to electrical power. For some embodiments, the flexible substrate may be between about 30 micrometers (μm) and about 1 cm thick.

Resistance of interconnects formed in a solar cell device affects the efficiency of the solar cell. Silver (Ag) interconnecting lines formed from a silver paste represent one interconnecting method. While silver has a lower resistivity (e.g., 1.59×10⁻⁸ ohm-m) than other common metals such as copper (e.g., 1.67×10^{31 8} ohm-m) and aluminum (e.g., 2.82×10⁻⁸ ohm-m), it costs orders of magnitude more than these other common metals. Therefore, one or more embodiments of the invention described herein are adapted to form a low cost and reliable interconnecting layer using an electrochemical plating process containing a common metal, such as copper. However, the electroplated portions of the interconnecting layer may contain a substantially pure metal or a metal alloy layer containing copper (Cu), silver (Ag), gold (Au), tin (Sn), cobalt (Co), rhenium (Rh), nickel (Ni), zinc (Zn), lead (Pb), and/or palladium (Pd). In one embodiment, the electroplated portion of the interconnect layer contains substantially pure copper or a copper alloy. In general, electroplating (ECP) process requires the step of cathodically biasing the one or more conductive elements that are to be plated upon relative to anode so that metal ions in an electrolyte, which is in contact with the conductive elements and anode, will deposit on the conductive elements to form a conductive layer.

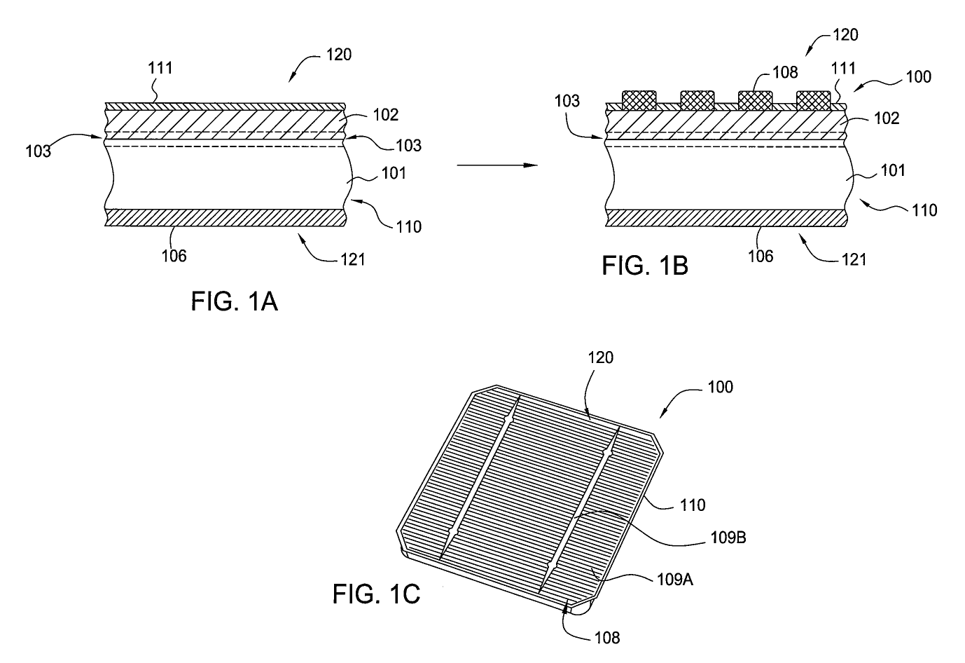

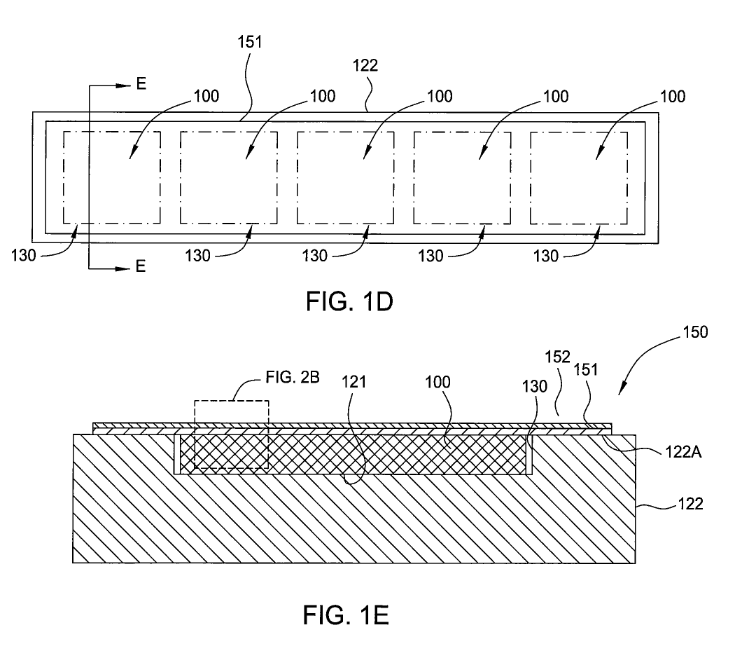

FIGS. 1B and 1C schematically depict one embodiment of a silicon solar cell 100 fabricated on a substrate 110 from an intermediate state shown in FIG. 1A, as described further herein. The substrate 110 includes a p-type base region 101, an n-type emitter region 102, and a p-n junction region 103 disposed therebetween. An n-type region, or n-type semiconductor, is formed by doping the semiconductor with certain types of elements (e.g., phosphorus (P), arsenic (As), or antimony (Sb)) in order to increase the number of negative charge carriers, i.e., electrons. Similarly, a p-type region, or p-type semiconductor, is formed by the addition of trivalent atoms to the crystal lattice, resulting in a missing electron from one of the four covalent bonds normal for the silicon lattice. Thus, the dopant atom can accept an electron from a neighboring atom's covalent bond to complete the fourth bond. The dopant atom accepts an electron, causing the loss of half of one bond from the neighboring atom and resulting in the formation of a “hole.” The solar cell device configurations illustrated in FIGS. 1A-1C, and other below, are not intended to be limiting as to the scope of the invention since other substrate and solar device region configurations can be metallized using the methods and apparatuses described herein without deviating from the basic scope of the invention.

When sunlight falls on the solar cell 100, energy from the incident photons generates electron-hole pairs on both sides of the p-n junction region 103. Electrons diffuse across the p-n junction to a lower energy level and holes diffuse in the opposite direction, creating a negative charge on the emitter and a corresponding positive charge builds up in the base. When an electrical circuit is made between the emitter and the base and the p-n junction is exposed to certain wavelengths of light, a current will flow. The electrical current generated by the semiconductor when illuminated flows through contacts disposed on the frontside 120, i.e. the light-receiving side, and the backside 121 of the solar cell 100. The top contact structure 108, as shown in FIG. 1C, is generally configured as widely-spaced thin metal lines 109A, or fingers, that supply current to larger bus bars 109B transversely oriented to the fingers. The back contact 106 is generally not constrained to be formed in multiple thin metal lines, since it does not prevent incident light from striking the solar cell 100. The solar cell 100 may be covered with a thin layer of dielectric material, such as silicon nitride (Si₃N₄) or silicon nitride hydride (SiₓN_{y}:H), to act as an anti-reflection coating layer 111, or ARC layer 111, that minimizes light reflection from the top surface of the solar cell 100. The ARC layer 111 may be formed using a physical vapor deposition (PVD) process, a chemical vapor deposition process, or other similar technique. An anneal step (>600° C.) may be used to further passivate the deposited ARC layer 111.

The contact structure 108 makes contact with the substrate and is adapted to form an ohmic connection with doped region (e.g., n-type emitter region 102). An ohmic contact is a region on a semiconductor device that has been prepared so that the current-voltage (I-V) curve of the device is linear and symmetric, i.e., there is no high resistance interface between the doped silicon region of the semiconductor device and the metal contact. Low-resistance, stable contacts ensure performance of the solar cell and reliability of the circuits formed in the solar cell fabrication process. The back contact 106 completes the electrical circuit required for the solar cell 100 to produce a current by forming a conductive layer that is in ohmic contact with p-type base region 101 of the substrate.

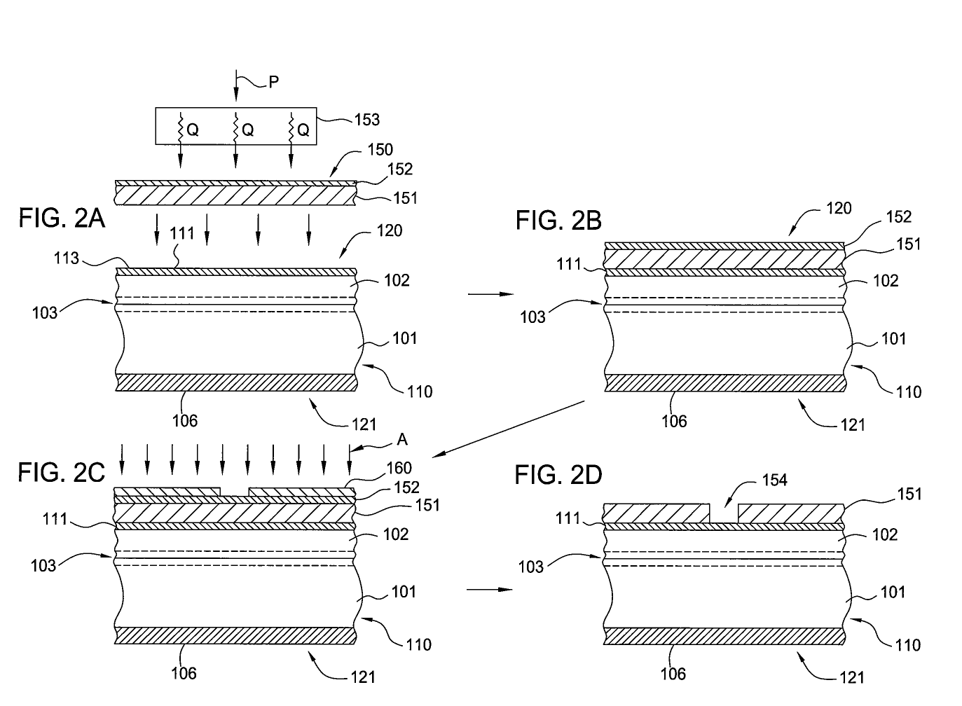

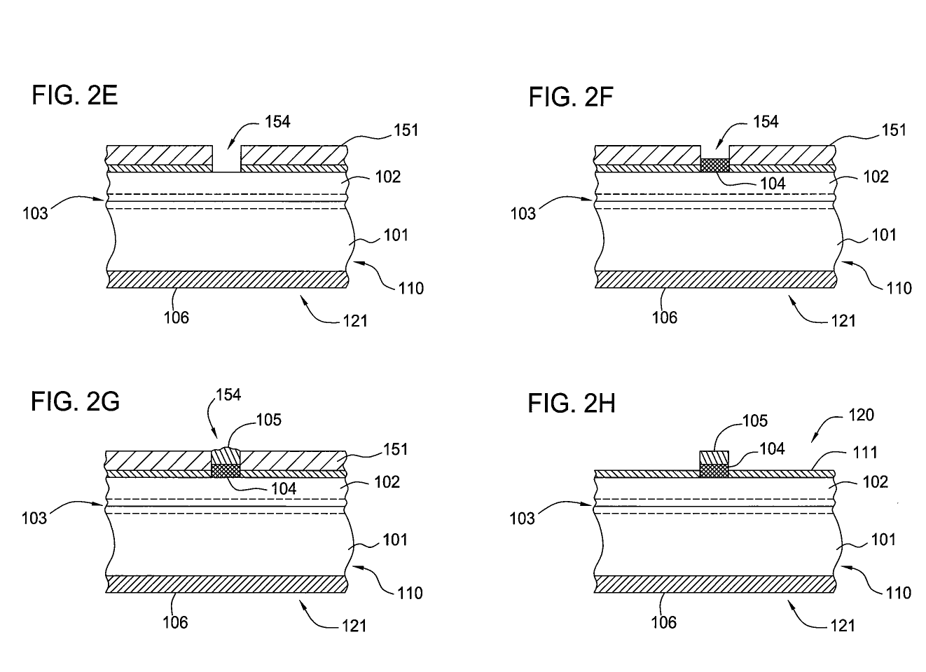

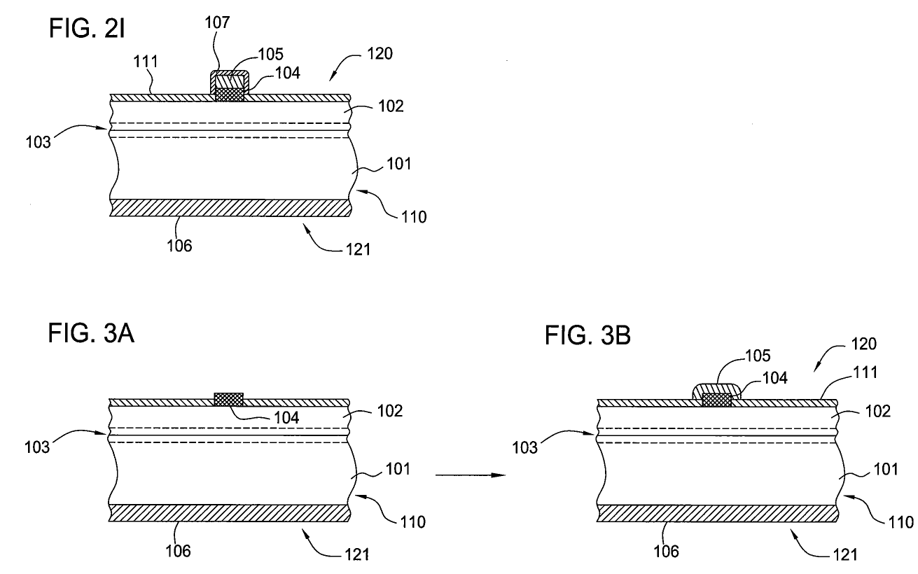

FIGS. 1D and 1E show a protective support 122 upon which the backside 121 of the solar cell 100 is disposed during manufacturing processes described herein. FIG. 1E represents a cross section taken across line E-E of FIG. 1D that shows a top view of the support 122. The protective support 122 may include a recess 130, or well, that is about the same depth as a thickness of the solar cell 100 and just slightly larger in dimension than the solar cell 100. In one aspect, the recess 130 is sized so that it is only about 1 mm larger than the substrate 110 dimensions to register and actively retain the substrate during processing. The support 122 may receive the solar cell 100 within the recess 130 when the solar cell 100 is in the intermediate state shown in FIG. 1A. For some embodiments, the support 122 includes multiple recesses (e.g., five in a row as shown in FIG. 1D) into which the respective solar cells 100 are disposed to facilitate time efficient simultaneous processing of more than one solar cell and act as the carrier for multiple solar cell substrates through the subsequent wet processing steps. The support 122 may provide structural rigidity that prevents breakage of the often fragile substrate 110 used to form the solar cell 100. The support 122 may be formed from a plastic (e.g., polypropylene), coated metal, glass, ceramic or other chemically compatible and structurally viable material. The support 122 thus allows the substrates 110 to be easily handled to allow the contact structure 108 to be easily formed. Further, the support 122 isolates the backside 121 from the various chemicals used in the wet processes described further herein. In some embodiments, a plastic material forms the support 122 and may include a complaint and/or sticky surface for temporary adherence to the back contact 106. While not shown in subsequent figures, the solar cell 100 may be disposed within the support 122 up until completion of the solar cell device or at least through an initial metallization steps used to form the contact structure 108. Accordingly, detail 2B in FIG. 1E corresponds to FIG. 2B for providing exemplary reference with respect to the following description.

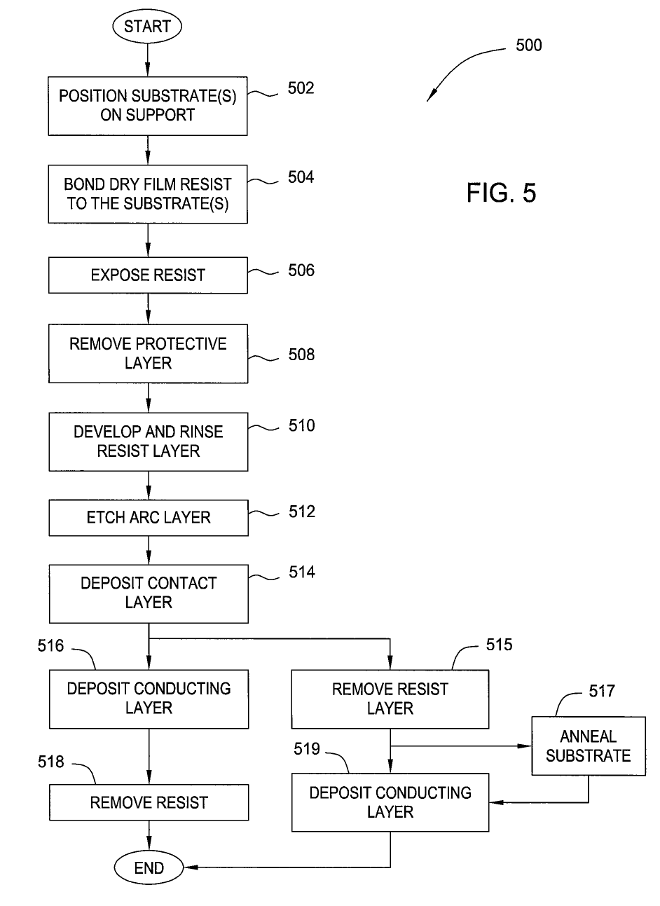

FIGS. 2A-2I illustrate schematic cross-sectional views of a solar cell during different stages in a processing sequence used to form a conductive layer on a surface of the solar cell, such as the contact structure 108 shown in FIG. 1B. FIG. 5 illustrates a process sequence 500, or series of method steps, that are used to form the contact structure 108 on a solar cell. The method steps found in FIG. 5 correspond to the stages depicted in FIGS. 2A-4B, which are discussed below.

In step 502, as illustrated in FIG. 2A, a composite resist 150 is positions over the ARC layer 111. In one embodiment, the substrate 110 is positioned in the support 122 (not shown in FIG. 2A) during step 502. As shown in FIG. 2A, in one embodiment, the composite resist 150 includes a carrier layer 152 and a photoresist material 151, which is a photosensitve material that generally changes one or more of properties when exposed to one or more forms of electromagnetic radiation. In one embodiment, the composite resist 150 includes a “negative” type photoresist material 151 that is bonded to a carrier layer 152. The carrier layer 152 is generally a polymeric type material that is used to support or retain the photoresist material 151 when the composite resist 150 is purchased, handled and/or formed in a roll or sheet fashion. As an example of a suitable commercially available composite resist 150 is made by DuPont® and sold as Riston®. In one embodiment, the photoresist material 151 is about 40 microns (μm) thick. One skilled in the art would appreciate that the use of a two component composite resist 150 material is not intended to be limiting as to the scope of the invention, since the use of “spin-on”, “spray-on” or “roll-on” photoresist materials can be used in one or more places within the process sequence discussed below without deviating from the basic scope of the invention. Also, while the photoresist material 151 of the composite resist 150 illustrated in the figures is a “negative” type photoresist material, some embodiments may utilize a “positive” type of photoresist without varying from the basic scope of the invention. Additional embodiments may include the use of a polymeric etch mask layer applied either by lamination, or one of the above alternate processes, and patterned by direct laser ablation to expose desired regions of the surface of the substrate. In such process flows the applied films (e.g., composite resist 150) may have the important function of sealing the edges and backside of the substrate being processed in the carrier, in addition to providing the template into which the front contact metal is formed. In such flows, it is also possible to choose a laser with sufficient energy and an appropriate wavelength (e.g., 355 nm), such that both the polymeric film and the ARC layer 111 (e.g., SiN layer) are both ablated simultaneously, exposing the bare silicon surface on which a selective growth of a metal layer (e.g., nickel, silver) may be accomplished by use of an electroless deposition process.

Referring to FIG. 2A, in the next step of the processing sequence, or step 504, heat (“Q”) and pressure (“P”) are applied to the composite resist 150 by a pressure applying device, such as a thrust plate 153 (e.g., heated plate, heated roller), to form a bond between the photoresist material 151 of the composite resist 150 and the substrate surface 113. In one embodiment, the photoresist material 151 is bonded to the substrate surface 113 and the support surface 122A (see FIG. 1E) to sealable enclose the substrate 110, such as isolate and/or prevent one or more surfaces of the substrate 110 from being exposed to the external environment. In this configuration, the composite resist 150 extends over an entire top of the substrate 110 and is larger than the recess 130 in the support 122 that is used to hold the substrate 110. The heat and pressure may bond the photoresist material 151 of the composite resist 150 to a surface of the substrate 110 (e.g., ARC layer 111) and a support surface 122A (FIG. 1E) of the support 122, thus enclosing the substrate 110. The amount of heat and pressure required to form a desirable bond between the various desirable surfaces will generally depend on the type of photoresist material, the nature of bonding surface, and the time and temperature used in the bonding process. For example, the bonding process is performed by applying adequate pressure to a roller that is set to a temperature of about 110° C. to cause the photoresist material 151 to bond to the support 122 and substrate surface 113. FIG. 2B illustrates the photoresist material 151 and carrier layer bonded to the ARC layer 111.

Next, during the exposure step, or step 506, a pattern mask 160, such as a metal mask (e.g., chrome on glass, silver on Mylar), is disposed on or over the photoresist material 151 and carrier layer 152 to protect selected portions of the photoresist material 151 from the optical radiation delivered during the subsequent part of the exposure step. It is generally desirable to leave the carrier layer 152 attached to the photoresist material 151 during the exposure step to prevent contact between the pattern mask 160 and the photoresist material 151. The photoresist material 151 is then exposed to desired types of electromagnetic radiation for a period of time (e.g., about 2-15 seconds), depicted by arrows “A” in FIG. 2C, which then causes the photoresist material to change chemically so that a desired pattern can be formed in the photoresist material 151. The amount of energy and the wavelength of the light used to expose the photoresist material 151 will vary depending on the type of photoresist material that is used.

Next, during the carrier layer removal step, or step 508, the carrier layer 152 is separated from the photoresist material 151, thus leaving the photoresist material 151 unprotected to allow the subsequent developing step (i.e., step 510) to be performed (FIGS. 2D and 5). Generally, the carrier layer 152 may be separated from the photoresist material 151 by use of heat or other conventional means. In some cases the carrier layer 152 is simply pealed away from the photoresist material 151. In one embodiment, it is desirable to only remove portions of the carrier layer 152 from the photoresist material 151 to provide a mask or provide additional support to regions of photoresist material 151 during processing. In one example, it may be desirable to remove only a portion of the carrier layer 152 so that a region remains over the support surface 122A of the support 122 and an unused edge region of the substrate 110.

As shown in FIG. 2D, after performing step 510, or the developing and rinsing steps, a desired pattern is formed in the photoresist material 151 on the surfaces of substrate 110. The desired pattern generally includes open regions, or channels 154, that are formed in the photoresist material 151. The channels 154 are formed at locations where the contact structure 108 is to be deposited. In one example, developing chemicals used to develop a Riston® type of the photoresist material 151 may include a bath of about 1% sodium carbonate (NaCO₃) or potassium carbonate (KCO₃) at about 30° C. for between about 30 and 120 seconds followed by a rinse in water. The bath used to develop photoresist material 151 will depend on the type of photoresist material used.

In the next step, or step 512, the ARC layer 111 is etched to expose desired regions of the substrate surface. FIG. 2E illustrates the effect of the etching process that is used to remove portions of the ARC layer 111 from the surface of the substrate 110 where it is exposed or not covered by the photoresist material 151. Removal of the portions of the ARC layer 111 can performed by using a buffered oxide etch (BOE) wet chemical process. In one embodiment, the BOE chemicals are heated to about 50° C. and the etching process is performed by exposing the desired substrate surfaces for about two minutes. The U.S. Patent Application Publication Numbers US2007/0099806 and US2007/0108404, which are herein incorporated by reference, describe exemplary BOE solutions and etching processes. Further, the BOE bath may also contain salts of metals, such as salts of nickel or palladium, which can deposit on the exposed silicon surfaces and promote the initiation of subsequent electroless deposition processes.

In one embodiment, following the BOE etching process, a separate palladium activation layer may be formed to prepare the surface of the n-type emitter region 102 for subsequent metallization steps described herein. An example of an exemplary palladium activation process that can be adapted for use with the various embodiments described herein is further described in the commonly assigned U.S. patent application Ser. No. 10/970,839 [Docket # APPM 8879], filed Sep. 21, 2004, which is herein incorporated by reference. Alternately, as indicated above, the BOE chemistry may contain a small amount of a palladium salt to achieve the same purpose.

In the contact layer formation step, or step 514, a conductive contact layer 104 is formed on the exposed surfaces of the substrate 110. FIG. 2F illustrates a contact layer 104 deposited on the n-type emitter region 102 within the channels 154 formed in the photoresist material 151. In one embodiment, an electroless nickel deposition process is used to form the contact layer 104 that comprises a primarily pure nickel layer that is between about 10 and about 3500 angstroms (Å) thick. In some cases, the electrolessly deposited nickel film may contain a high amount of phosphorus (e.g., about 5% P). In one embodiment, an electroless nickel deposition process is used to form the contact layer 104 that comprises a nickel phosphorous (NiP) layer that is between about 10 and about 3500 angstroms (Å) thick. In one aspect, it is desirable to use a deposition solution that has a pH that is acidic, such as at about 4-6.5, to prevent removal and/or attack of the photoresist material 151. Further, contents of a bath for the electroless nickel deposition process may include nickel sulfate (NiSO₄), ammonia fluoride (NH₄F), hydrogen fluoride (HF), and hypophosphite (H₂PO₂⁻). For example, the bath may be at 60° C. and include about 15 grams per liter (g/L) of NiSO₄, 25 g/L of NH₄F, and 25 g/L monoammonium hypophosphate (NH₄H₂PO₂) and be exposed to the substrate surface for about 2 minutes. An example of an exemplary preparation and electroless nickel deposition process is further described in the commonly assigned U.S. patent application Ser. No. 11/553,878 [Docket # APPM 10659.P1], filed Sep. 27, 2006, and the commonly assigned U.S. patent application Ser. No. 11/385,041 [Docket # APPM 10659], filed Mar. 20, 2006, which are both herein incorporated by reference.

In an alternate embodiment, the process of forming the contact layer 104 is completed by a nickel electroplating process that is performed directly on to the surface of the substrate 110, such as the n-type emitter region 102. The contents of the electrolyte that can be used to perform the nickel plating process may include nickel sulfamate (NiSO₃NH₂), nickel chloride (NiCl₂), and boric acid (H₃BO₃) maintained at a bath temperature of about 60° C. and a pH of about 4.5. Current densities during processing may range from 0.1 to 4 A/dm². While electroplated films will result in a more pure nickel deposit, as compared to films formed by use of an electroless deposition process, the adhesion of the electroplated film to the substrate surface may not be as good as an electrolessly deposited film.

In step 516, as illustrated in FIG. 2G, a conducting layer 105 is deposited on the contact layer 104 to form the major electrically conducting part of the contact structure 108. In one aspect, the conducting layer is deposited so that is substantially fills the channels 154 formed in the photoresist material 151. In one embodiment, the formed conducting layer 105 is between about 2000 and about 10,000 angstroms (Å) thick and contains a metal, such as copper (Cu), silver (Ag), gold (Au), tin (Sn), cobalt (Co), rhenium (Rh), nickel (Ni), zinc (Zn), lead (Pb), and/or palladium (Pd). In one embodiment, the conducting layer 105 is formed by depositiing copper on the conducting layer 105. As previously mentioned, other metals, such as silver or conventional solder materials, may replace or be used in addition to copper in the conducting layer 105. The process of forming the conductive layer 105 may occur by one or more various techniques such as electrochemical plating (ECP), electroless plating (e.g., copper deposition, silver deposition), or in the case of a solder alloy by filling the patterned photoresist layer with an appropriate solder paste and heating it to tis melting and reflow temperature. An example of an examplary electroplating process is further described in the commonly assigned U.S. patent application Ser. No. 11/552,497 [Docket # APPM 11227], filed Sep. 24, 2006, and the commonly assigned U.S. patent application Ser. No. 11/566,205 [Docket # APPM 11230], filed Dec. 1, 2006, which are both herein incorporated by reference. In general, it is desirable to make electrical contact during the electrochemical plating process to regions of the bus bars 109B (FIG. 1B) near the edge of the substrate 110, since they are generally sized to carry current and thus allow uniform deposition of conducting layer 105 over the widely-spaced thin metal lines 109A and the larger bus bars 109B. The use of the protective support 122 and photoresist material 151 further enables the isolation of the back contact 106 from the electrolyte used in the ECP process and thus allows for a rapid and uniform deposition process without attack of the back contact 106 metal layer.

In one embodiment of step 516, a silver ink material is deposited into the channels 154, the excess ink material is wiped from the photoresist material 151, and then the ink ladened solar cell is heated to a desired temperature to remove the organic components from the ink, sinter the silver particles, and form an electrical connection with the contact layer 104. In another embodiment, the conducting layer 105 is formed using a conventional silver paste material that is disposed on the surface of the substrate and then “squeegeed” so that the channels 154 are substantially filled with the conventional silver paste material. The silver paste on the solar cell is then heated to a desired temperature to remove the organic components from the paste, sinter the silver particles, and form an electrical contact with the contact layer 104. In either case the ink or the paste may be heated to about 300° C. to melt/consolidate the silver material, while the underlying layer of electroless nickel begins to form a silicide layer to improve electrical contact and adhesion.

In another embodiment of step 516, a conventional wave soldering process is used to form the conducting layer 105. In one embodiment, a tin/silver solder material (e.g., of 98/2 Sn/Ag solder) is used to form the conducting layer 105. In one aspect, after performing the wave soldering process a hot air knife type clean process is used to aid in the removal of excess solder material extending above the top of the channel 154.

In one embodiment, the conducting layer 105 is formed from a series of deposited metal layers formed using one or more metal deposition steps, such as ECP, electroless plating, soldering processes, or conventional processes (i.e., metal CVD processes). In one embodiment, the conducting layer 105 may include a layer of silver deposited by electroless or ECP procedures, and then a layer formed from a solder material, such as silver/zinc (AgZn), using a wave soldering process. An electroless silver deposition process has some advantages over conventional electroless deposition processes since the bath can have an acidic pH and doesn't need an added coating to improve future electrical connections to the solar cell (e.g., soldering steps).

In one embodiment of the process sequence 500, a rapid thermal processing step, or step 517, is performed on the substrate 110 after soldering, deposition of the silver paste, or other similar steps. The rapid thermal processing step (e.g., at about 300° C.) can be used to melt/consolidate the solder and form nickle silicide (NiₓSi_{y}) at an interface between the contact layer 104 and the n-type emitter region 102. Exemplary ECP procedures include plating of copper, copper followed by tin, copper followed by silver, or silver. The conducting layer 105 may include ECP deposited copper and a solder, such as tin/copper/silver (SnCuAg). In one embodiment of the process sequence 500, a forming gas anneal step is performed after stripping the photoresist material 151 may generate a nickel silicide.

In step 518, as illustrated in FIG. 2H, the photoresist material 151 is removed from the surface of the substrate 110 leaving the contact layer 104 and conducting layer 105 on surface. The photoresist material 151, which may be removed using a conventional photoresist stripping wet chemistries, such as Propylene Glycol Methyl Ether (PGME), Methyl Ethyl Ketone (MEK), Monoethanolamine (MEA), or NMP. Typically, the wet chemistries have a basic pH and are maintained at elevated temperatures to dissolve or strip away the photoresist material 151. In one embodiment, a conventional ashing process is used to remove the photoresist material.

In one embodiment of step 518, the conventional wet chemistry may also include tin and/or silver ions that are use to form an immersion coating 107 on the contact layer 104 and the conducting layer 105 during the photoresist removal process. In this case, the a tin and/or a silver layer is formed to substantially cover the contact layer 104 and conducting layer 105, as shown in FIG. 2I. In some embodiments, the coating 107 protects the contact layer 104 and the conducting layer 105 from oxidation and may be deposited by use of chemicals that can promote an autocatalytic reaction at the surface of the contact layer 104 and the conducting layer 105. In one embodiment, the coating 107 protects the contact layer 104 and the conducting layer 105 from oxidation if desired and may be deposited by a soldering process.

After stripping away the photoresist material 151 and rinsing the substrate 110 is removed from the support 122 and thus substantially completes the assembly of the contact structure 108 on the solar cell device. The combined contact and conducting layers 104, 105 and coating 107 form the contact structure 108 shown in FIG. 1B.

The aforementioned process includes a single photolithographic procedure that does not require expensive and time consuming alignment steps that are needed in conventional solar cell metallization processes. Further, the process sequence may occur entirely under wet conditions from one bath to the next, thus reducing the number of processing steps. Another advantage of the process relates to the ability to carry and protect the often very thin and fragile solar substrate on only one support throughout the process without needing to transfer the substrate or apply pressure to the substrate except when laminating the substrate onto the support. The use of the protective support 122 and photoresist material 151 further enables the isolation of the back contact 106 from the electrolyte used in the ECP process and thus allows for a rapid and uniform deposition process without attack of the back contact metal layer.

FIGS. 3A and 3B illustrate schematic cross-sectional views of a partially manufactured solar cell after performing steps 502-514, and thus after the stage of contact structure 108 formation process illustrated in FIG. 2F as set forth already herein. Therefore, prior to depositing the conductive layer 105 (i.e., step 516 or step 519), the photoresist material 151 is stripped from the surface of the substrate (i.e., step 515). The process of removing the photoresist layer in step 515 is generally the same as discussed above in conjunction with step 518 and FIGS. 2H-2I. The removal of the photoresist material 151 thus enables the temperature of the substrate 110 to be raised to a temperature that would cause damage to the photoresist material 151 and is sufficient to anneal the contact layer 104 or promote silicide formation between the contact layer 104 and the substrate surface. The annealing process, or step 517, is performed at a suitable temperature (e.g., about 200-350° C.) and duration (e.g., about two minutes) to produce a low resistance metal silicide (e.g., the NiSi) at the contact layer/n-type emitter region interface and may enhance bonding and contact of the contact layer 104 with the n-type emitter region 102.

In the next step, as shown in FIG. 3B, the conductor layer 105 is deposited on the contact layer 104 after the performing step 515. In one embodiment, the conductor layer 105 is deposited on the contact layer 104 after the performing steps 515 and 517. In general, step 519 is the same or similar to the process step 516 discussed above. In some embodiments, copper, tin, or silver are deposited by use of an electrochemical plating process to form the conductor layer 105 on the contact layer 104. Also, in one embodiment, a solder cap, similar to coating 107 shown in FIG. 2I, is formed on the conductor layer 105 by use of an electroplating process or electroless process to prevent subsequent oxidation or corrosion of the conductor layer 105.

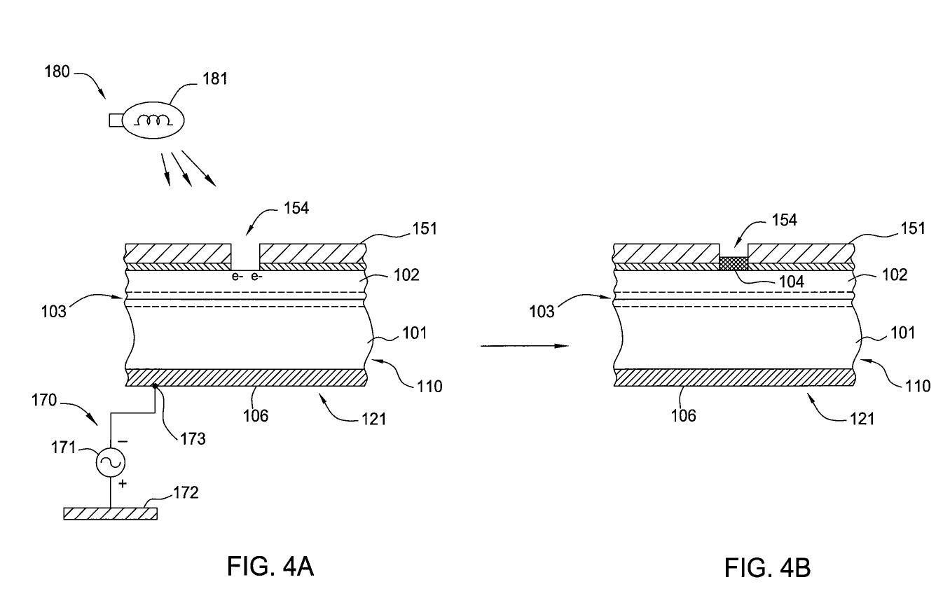

FIG. 4A illustrates a schematic cross-sectional view of a solar cell substrate 110 after steps 502-512 have been performed, and thus after the stage of contact structure 108 formation process illustrated in FIG. 2E as set forth already herein. FIG. 4B, which is the same as FIG. 2F, illustrates the state of that substrate after performing the galvanic deposition enhancement process shown in FIG. 4A, and thus allows steps 516-518 or steps 515-519 to then be performed on the substrate 110. During the galvanic deposition enhancement process, illustrated in FIG. 4A, a contact layer 104 is formed by exposing the surface of the solar cell to light to promote the deposition of metal ions contained in an electrolyte to be disposed on the substrate surface. In one embodiment, a puddle of the electrolyte is disposed on a surface of the solar substrate that is also being exposed to optical radiation. The exposure of the solar cell to light will cause the n-type region of the solar cell to generate electrons that can be used to promote a reaction between the metal ions in the electrolyte and the solar cell surface to form the contact layer 104 on the surface of the substrate 110. For some embodiments, addition of a lighting system 180 and galvanic coupling system 170 facilitate deposition of the contact layer 104 that may otherwise be deposited according to the foregoing procedures. The lighting system 180 includes a light source 181 for illuminating the substrate 110 and thereby generating electrons in the n-type emitter region 102 to promote plating of the contact layer 104.

In one embodiment, a galvanic coupling system 170 is used to avoid or prevent galvanic attack of the back contact 106 layer during one or more of the steps discussed above. Galvanic attack of the back contact layer 106 will occur when the electrolyte disposed on the front surface substrate (e.g., n-type region) is also in contact with the back contact layer 106. The galvanic couple can cause corrosion of the backside contact 106, which can be alleviated by enclosing the substrate between the composite resist 150 and the support 122, as discussed in conjunction with FIGS. 1D and 1E above. If isolation of the back contact is not enough, the galvanic coupling system 170 can be used. The galvanic coupling system 170 generally includes a potentiostat 171 and an anode 172, which is placed in contact with the electrolyte so that the anode 172 will acts as a sacrificial anode due to the voltage supplied by the potentiostat 171. In one embodiment, the potentiostat 171 is electrically connect to the back contact layer 106 by use of a connection pin 173 (e.g., conventional electrical contacting element (e.g., metal pins)) and to an anode 172, which are both disposed within the recess 130 (FIG. 1E), to prevent damage to the back contact 106 if electrolyte comes in contact with front surface of the substrate and the back contact 106. The voltage bias applied by the potentiostat will depend on the various types of metals that are in contact with the electrolyte.

### Alternate Metallization Methods

### Selective Etching Method

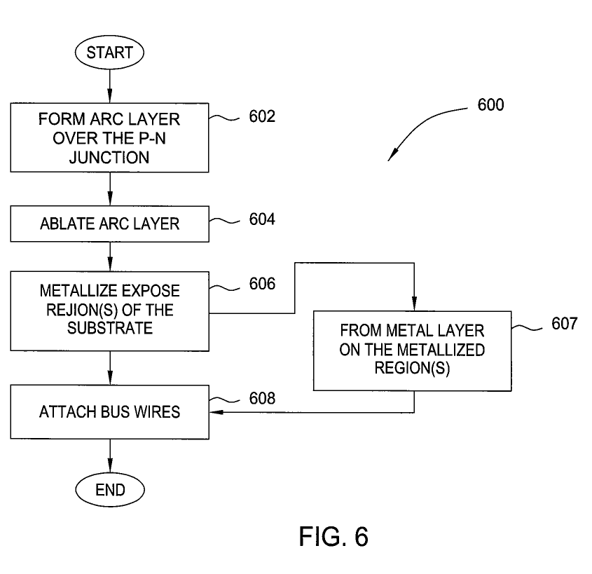

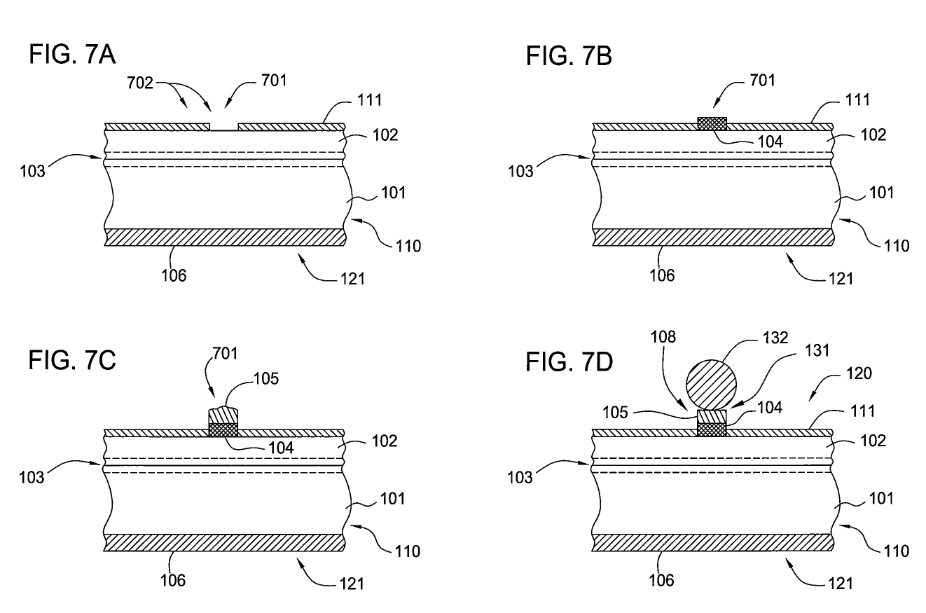

FIGS. 7A-7D illustrate schematic cross-sectional views of a solar cell during different stages in a processing sequence used to form a conductive layer on a surface of the solar cell, such as the contact structure 108 shown in FIG. 1B. FIG. 6 illustrates a process sequence 600, or series of method steps, that are used to form the contact structure 108 on the solar cell. The method steps found in FIG. 6 correspond to the stages depicted in FIGS. 7A-7D, which are discussed herein.

In step 602, as discussed above, a p-n junction of a solar cell device (e.g., reference numeral 103) is formed having an ARC layer 111 formed on a surface of the substrate (i.e., reference numeral 110 in FIG. 1A) via conventional means. It should be noted that the backside contact (e.g., reference numeral 106 in FIG. 1A), as in any of the steps discussed above, need not be formed prior to metalizing a portion of the surface 702 of the substrate 110 (FIG. 7A).

In the next step, or step 604, the ARC layer 111 is etched to expose desired regions of the substrate surface, or surface(s) 701, where the contact structure 108 is to be formed. In one embodiment, the ARC layer 111 is etched using a beam of energy, for example, optical radiation (e.g., laser beam) or an electron beam to ablate desired regions of the ARC layer 111. FIG. 7A illustrates a substrate that has a portion of the ARC layer 111 removed from the surface 702 of the substrate 110. Optionally, it may be desirable to clean the surface 702 of the substrate 110 using a wet cleaning process.

In the contact layer formation step, or step 606, a conductive contact layer 104 is formed on the exposed regions, or surface(s) 701, of the substrate 110. FIG. 7B illustrates a contact layer 104 deposited on the n-type emitter region 102. In one embodiment, an electroless nickel deposition process is used to form the contact layer 104 that comprises a primarily a pure nickel layer that is between about 10 and about 3500 angstroms (Å) thick. In some cases, the deposited nickel film may contain a high amount of phosphorus (e.g., about 5% P). Further, contents of a bath for the electroless nickel deposition process may include nickel sulfate (NiSO₄), ammonia fluoride (NH₄F), hydrogen fluoride (HF), and hypophosphite (H₂PO₂⁻). For example, the bath may be at 60° C. and include about 15 grams per liter (g/L) of NiSO₄, 25 g/L of NH4F, and 25 g/L monoammonium hypophosphate (NH₄H₂PO₂) and be exposed to the substrate surface for about 2 minutes. An example of an exemplary preparation and electroless nickel deposition process is further described in the commonly assigned U.S. patent application Ser. No. 11/553,878 [Docket # APPM 10659.P1], filed Sep. 27, 2006, and the commonly assigned U.S. patent application Ser. No. 11/385,041 [Docket # APPM 10659], filed Mar. 20, 2006, which are both herein incorporated by reference. In another embodiment, the electroless nickel deposition process may be completed at a temperature between about 75-85° C. and use a solution containing about 25 grams of nickel acetate (Ni(OOCCH₃)₂.4H₂O), 50 grams of 42% hypophosphorous acid (H₃PO₂), and enough ethylenediamine to achieve a pH of 6.0, which is added to a 6:1 BOE solution. The nickel deposition rate that can be achieved is generally between 250-300 angstrom/minute. The U.S. Patent Application Publication Numbers US2007/0099806 and US2007/0108404, which are herein incorporated by reference, describe exemplary BOE solutions and etching processes.

In step 607, as illustrated in FIG. 7C, a conducting layer 105 is optionally deposited on the contact layer 104 to form the major electrically conducting part of the contact structure 108. In one embodiment, the formed conducting layer 105 is between about 2000 and about 50,000 angstroms (Å) thick and contains a metal, such as copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, the conducting layer 105 is formed by depositing silver (Ag) on the contact layer 104 using an electroless silver deposition process that inherently selectively forms a metal layer on the contact layer 104.

In step 608, as illustrated in FIG. 7D, a bus wire 130 is attached to at least a portion of the contact structure 108 to allow portions of the solar cell device to be connected to other solar cells or other external devices. In general, the bus wire 130 is connected to the contact structure 108 using a soldering material 131 that may contain a solder material (e.g., Sn/Pb, Sn/Ag). In one embodiment, the buss wire 132 is a pre-formed wire material that is cut to a desirable length before it is bonded to the contact structure 108. In one embodiment, the bus wire 130 is about 200 microns thick and contains a metal, such as copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, each of the buss wires 132 are formed from a wire that is about 30 gauge (AWG: ˜0.254 mm) or smaller in size. In one embodiment, the bus wire is coated with a solder material, such as a Sn/Pb or Sn/Ag solder material. It should be noted that while FIG. 7D illustrates the bus wire 130 attached to the optionally deposited conducting layer 105 this configuration is not intended to be limiting to the scope of the invention described herein, since the bus wire 130 could be directly attached to the contact layer 104 without deviating from the basic scope of the invention described herein.

### Ink Deposition Process

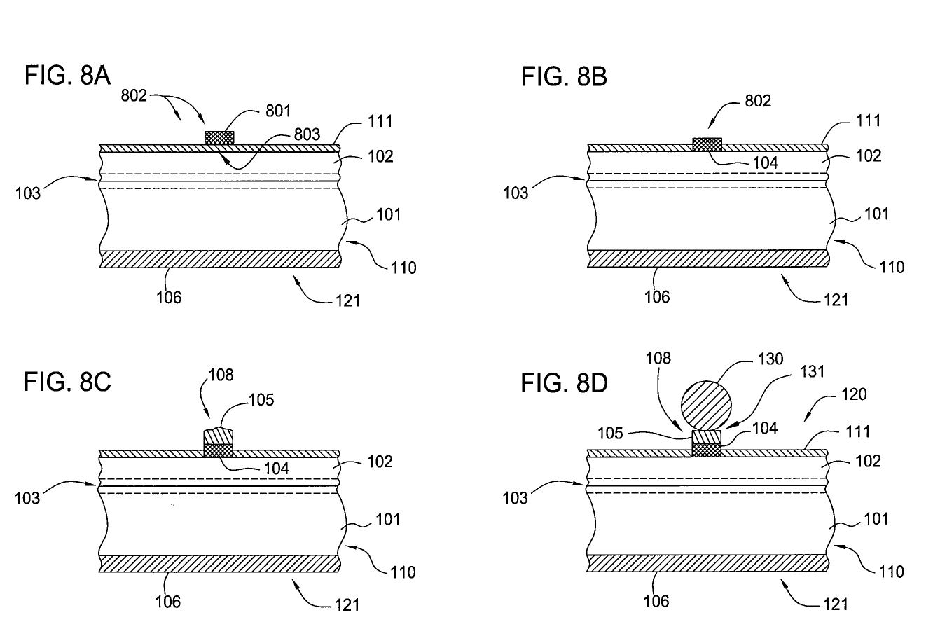

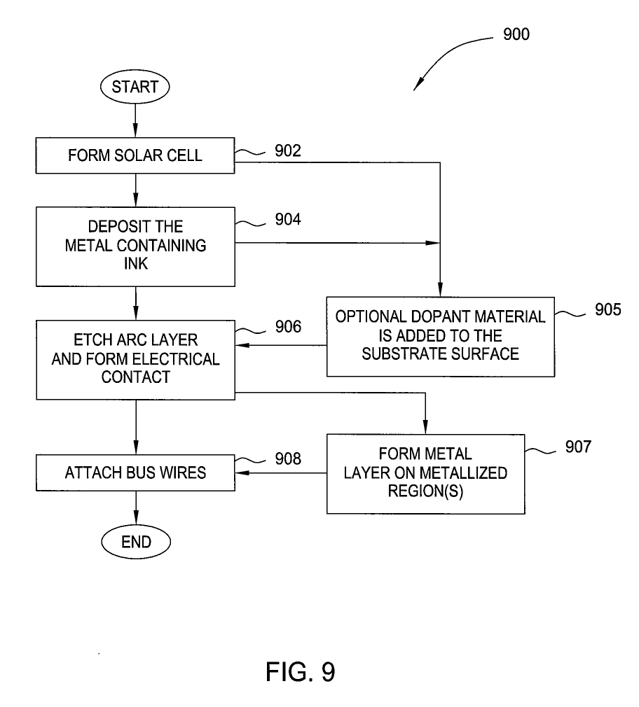

FIGS. 8A-8D illustrate schematic cross-sectional views of a solar cell during different stages in a processing sequence used to form a conductive layer on a surface of the solar cell, such as the contact structure 108 shown in FIG. 1B. FIG. 9 illustrates a process sequence 900, or series of method steps, that are used to form the contact structure 108 on a solar cell. The method steps found in FIG. 9 correspond to the stages depicted in FIGS. 8A-8D, which are discussed herein.

In step 902, as discussed above a solar cell is formed having an arc layer 111 formed on a surface of the substrate 110 (See FIG. 1A) via conventional means. It should be noted that the backside contact (e.g., reference numeral 106 in FIG. 1A), as in any of the steps discussed above, need not be formed prior to metalizing a portion of the surface 802 of the substrate 110 (FIG. 8A).

In the next step, or step 904, a metal containing ink 801 material is selectively deposited on the ARC layer 111 by use of a conventional ink jet printing, rubber stamping or other similar process to form and define the regions where the contact structure 108 (i.e., fingers 109A and bus bars 109B) are to be formed. In one embodiment, metal containing ink 801 is a nickel containing ink that is formulated to etch the ARC layer 111 and metalize the underlying surface 803 of the substrate 110. In one embodiment, the nickel containing ink contains: 10 grams of nickel acetate (Ni(OOCCH₃)₂.4H₂O), 10 grams of 42% hypophosphorous acid (H₃PO₂), 10 grams of polyphosphoric acid (H₆P₄O₁₃), 3 grams of ammonium fluoride (NH₄F) and 2 g of 500 MW Polyethylene glycol (PEG). In one embodiment, it may be desirable to add a desirable amount of methanol or ethanol to the nickel containing solution.

In the contact layer formation step, or step 906, the substrate is heated to a temperature of between about 250-300° C. which causes the chemicals in the ink to etch the ARC layer 111 and metalize the underlying surface 803 of the substrate. In one embodiment, the process of heating a nickel containing metal containing ink 801 causes a silicon nitride (SiN) containing ARC layer 111 to be etched and a nickel silicide (NiₓSi_{y}) to form on the surface of upper surface of the substrate 110, such as the n-type emitter region 102. FIG. 8B illustrates a contact layer 104 formed on the n-type emitter region 102. In one embodiment, an electroless nickel deposition process is used to form the contact layer 104 that comprises a primarily nickel layer that is between about 10 and about 2000 angstroms (Å) thick.

In step 907, as illustrated in FIG. 8C, a conducting layer 105 is optionally deposited on the contact layer 104 to form the major electrically conducting part of the contact structure 108. In one embodiment, the formed conducting layer 105 is between about 2000 and about 50,000 angstroms (Å) thick and contains a metal, such as copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, the conducting layer 105 is formed by depositing silver (Ag) on the contact layer 104 using an electroless silver deposition process that inherently selectively forms a metal layer on the contact layer 104.

In step 908, as illustrated in FIG. 8D, a bus wire 130 is attached to at least a portion of the contact structure 108 to allow portions of the solar cell device to be connected to other solar cells or external devices. In general, the bus wire 130 is connected to the contact structure 108 using a soldering material 131 that may contain a solder material (e.g., Sn/Pb, Sn/Ag). In one embodiment, the bus wire 130 is between about 2 microns thick and contains a metal, such as copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, the bus wire is coated with a solder material, such as a Sn/Pb or Sn/Ag solder material.

In one embodiment, steps 904 and 906 may be changed to provide an alternate technique that is used to form the contact structure 108. In the alternate version of step 904, rather than selectively depositing the metal containing ink 801 on the surface of the ARC layer 111 the ink is spread or deposited across the surface 802 of the substrate 110, or over desired regions of the substrate, by use of a simple spin-on, spray-on, dipping, or other similar technique. In the alternate version of step 906, a beam of energy, such optical radiation (e.g., laser beam) or an electron beam, is delivered to the surface of the substrate to selectively heat regions of the substrate to causes the chemicals in the ink in these regions to etch the ARC layer 111 and metalize the underlying surface 803 of the substrate. In one embodiment, the delivery of a beam of energy causes the a nickel containing metal containing ink 801 in the heated regions to etch a silicon nitride (SiN) containing ARC layer 111 and form a nickel silicide (NiₓSi_{y}) on the surface of upper surface of the substrate 110, such as the n-type emitter region 102. The unheated regions of the ink may then be rinsed from the surface of the substrate if desired.

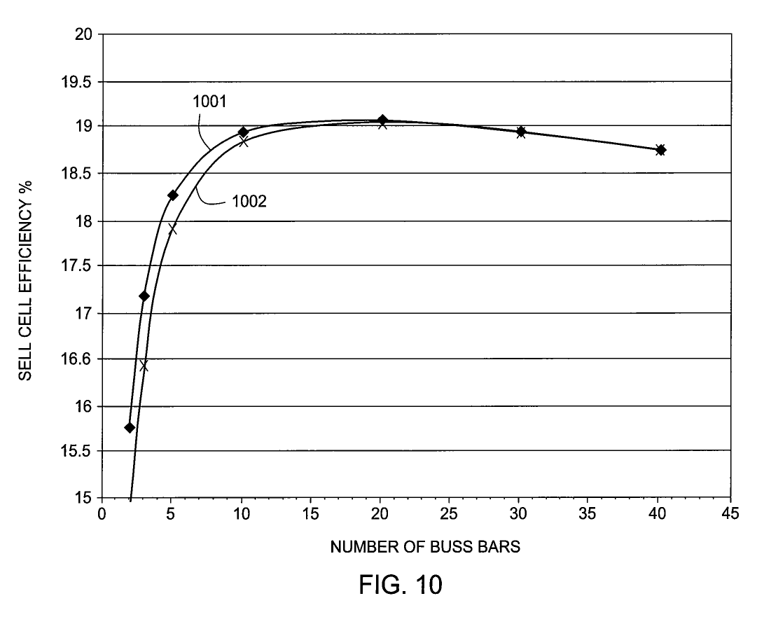

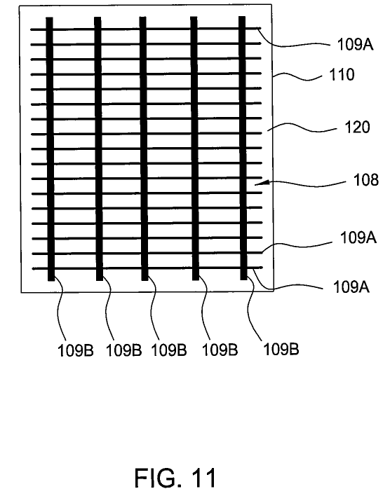

Referring to FIGS. 1C, 10 and 11, in one embodiment, the solar cell 100 has more than two of the major current carrying bus bars 109B (FIG. 11) that are transversely oriented relative to the fingers 109A. FIG. 10 is a graph illustrating the increase in efficiency of a solar cell versus the number of current carrying bus bars 109B that are oriented and placed on the front surface of a solar cell substrate. Line 1001 illustrates the effect of varying the number of 0.2 micron wide buss bars 109B to an array of transversely oriented fingers that are 5 microns thick, and line 1002 illustrates the effect of varying the number of 0.2 micron wide buss bars 109B to an array of transversely oriented fingers that are 1 microns thick. As shown in FIG. 10, it is believed that by increasing the number of bus bars 109B the solar cell efficiency is increased due to the reduction in the series resistance in the formed contact structure; however, as the number of bus bars 109B increase, the shadowed area created by the additional buss bars 109B increases causing the solar efficiency to eventually start to decrease. Therefore, in one embodiment, there are greater than 10 bus bars 109B evenly transversely distributed relative to the fingers 109A across the surface of the solar cell 100. In another embodiment, there are between about 7 and about 15 bus bars 109B that are evenly transversely distributed relative to the fingers 109A across the surface of the solar cell 100. In one case the 7 to about 15 bus bars are 200 microns wide and 200 microns thick. In the case where multiple buss bars 109B, such as greater than two, are used in a solar cell the area covered by each bus bar 109B can be reduced to reduce the percentage of surface area covered by these metalized regions, but still have a desirable cross-section to adequately and efficiently deliver the current to the external devices connect to the solar cell. In one embodiment, the fingers 109A are between about 0.50 microns (μm) and about 50 μm in width and have a spacing of about 2 mm, while the bus bars 109B are between about 1-5 microns (μm) in width and have a spacing of about 1 cm. In this configuration the thickness of the fingers 109A may be between about 1 to about 5 microns, and the thickness of the bus bars 109B may be about 200 microns. In one embodiment, one or more bus wires 130 are connected to each of the bus bars 109B that are spaced about 1 cm apart. In one example, the buss wires 132 are 200 microns in width and the bus bars 109B are between about 1-5 microns (μm) in width. In one embodiment, a bus wire 130 is connected to each of the bus bars 109B and a bus wire 130 is also connected to each of transversely oriented fingers 109A to improve the series resistance of the circuit (e.g., top contact structure) formed on the front surface of a solar cell.

### Doped Contact Metallization Process

In one embodiment of the process sequence 900, an etchant and/or dopant containing material (e.g., a phosphorous containing material) is disposed on the surface of the substrate to etch and/or dope a region of the underlying layer 803 during the subsequent step 906. In one embodiment, a doping material is added to the metal containing ink solution so that an improved metal to silicon interface can be formed.

Referring to FIG. 9, in step 905 a doping material is spread or deposited across the face of the substrate, or over desired regions of the substrate, by use of a simple spin-on, spray-on, dip or other similar technique. In one embodiment, the doping material may comprise polyacrylic acid (CH₂CHCOOH)ₓ, hypophosphorous acid (H₃PO₂), and a dye or pigment material.

In the another alternate version of step 906, a beam of energy, such optical radiation (e.g., laser beam) or an electron beam, is delivered to the surface of the substrate to selectively heat regions of the substrate to remove the ARC layer 111 from the surface of the substrate (e.g., similar to step 604), but also cause the chemicals in the doping material to react and dope the materials within the underlying surface 803 of the substrate.

In the next step a conductive contact layer 104 is formed on the exposed regions of the substrate. In one embodiment, an electroless nickel deposition process is used to form the contact layer 104 that comprises a primarily pure nickel layer that is between about 10 and about 3500 angstroms (Å) thick over the doped regions. In some cases, the deposited film may contain a high amount of phosphorus (e.g., about 5% P). Further, contents of a bath for the electroless nickel deposition process may include nickel sulfate (NiSO₄), ammonia fluoride (NH₄F), hydrogen fluoride (HF), and hypophosphite (H₂PO₂⁻). For example, the bath may be at 60° C. and include about 15 grams per liter (g/L) of NiSO4, 25 g/L of NH4F, and 25 g/L monoammonium hypophosphate (NH₄H₂PO₂) and be exposed to the substrate surface for about 2 minutes. An example of an exemplary preparation and electroless nickel deposition process is further described in the commonly assigned U.S. patent application Ser. No. 11/553,878 [Docket # APPM 10659.P1], filed Sep. 27, 2006, and the commonly assigned U.S. patent application Ser. No. 11/385,041 [Docket # APPM 10659], filed Mar. 20, 2006, which are both herein incorporated by reference. In one embodiment, the electroless nickel deposition process may be completed at a temperature between about 75-85° C. and use a solution containing about 25 grams of nickel acetate (Ni(OOCCH₃)₂.4H₂O), 50 grams of 42% hypophosphorous acid (H₃PO₂), and enough ethylenediamine to achieve a pH of 6.0, which is added to a 6:1 BOE solution. The deposition rate that can be achieved is generally between 250-300angstrom/minute. The U.S. Patent Application Publication Numbers US2007/0099806 and US2007/0108404, which are herein incorporated by reference, describe exemplary BOE solutions and etching processes.

In the next step a conducting layer 105 is optionally deposited on the contact layer 104 to form the major electrically conducting part of the contact structure 108. In one embodiment, the formed conducting layer 105 is between about 2000 and about 50,000 angstroms (Å) thick and contains a metal, such as copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, a copper (Cu) containing conducting layer 105 is deposited on the contact layer 104 by use of an electrochemical plating process (e.g., copper deposition, silver deposition). An example of an examplary electroplating process is further described in the commonly assigned U.S. patent application Ser. No. 11/552,497 [Docket # APPM 11227], filed Sep. 24, 2006, and the commonly assigned U.S. patent application Ser. No. 11/566,205 [Docket # APPM 11230], filed Dec. 1, 2006, which are both herein incorporated by reference. In general, it is desirable to make electrical contact during the electrochemical plating process to regions of the bus bars 109B (FIG. 1B) near the edge of the substrate 110, since they are generally sized to carry current and thus allow uniform deposition of conducting layer 105 over the widely-spaced thin metal lines 109A and the larger bus bars 109B. In another embodiment, the conducting layer 105 is formed by depositing silver (Ag) on the contact layer 104 using an electroless silver deposition process that inherently selectively forms a metal layer on the contact layer 104.

In the next step a bus wire 130 may be attached to at least a portion of the contact structure 108 to allow portions of the solar cell device to be connected to other solar cells or external devices. In general, the bus wire 130 is connected to the contact structure 108 using a soldering material 131 that may contain a solder material (e.g., Sn/Pb, Sn/Ag). In one embodiment, the bus wire 130 is about 200 microns thick and contains a metal, such as copper (Cu), silver (Ag), gold (Au), tin (Sn), cobalt (Co), rhenium (Rh), nickel (Ni), zinc (Zn), lead (Pb), palladium (Pd), and/or aluminum (Al). In one embodiment, the bus wire is coated with a solder material, such as a Sn/Pb or Sn/Ag solder material.

While the foregoing is directed to embodiments of the present invention, other and further embodiments of the invention may be devised without departing from the basic scope thereof, and the scope thereof is determined by the claims that follow.

What is claimed is:

1. A method of forming a solar cell device on a solar cell substrate, comprising:
disposing a photoresist layer on a surface of a substrate and a surface of a substrate carrier to substantially enclose the substrate within a space formed between the resist layer and the substrate carrier;
patterning the photoresist layer disposed on the surface of the substrate to expose one or more regions of the surface of the substrate;
removing material from the one or more regions of the surface so that a silicon containing material is exposed;
electrolessly depositing a contact layer on the exposed silicon containing material, wherein the substrate remains disposed within the space during the patterning, the removing material, and the electrolessly depositing processes; and
depositing a fill layer on the contact layer.

2. The method of claim 1, wherein depositing the fill layer occurs while the photoresist layer remains on the surface of the substrate.

3. The method of claim 1, wherein the material removed from the one or more regions is a silicon nitride containing layer.

4. The method of claim 1, wherein depositing the fill layer comprises electroplating silver or tin on the contact layer.

5. The method of claim 1, wherein depositing the fill layer comprises soldering a tin containing material on the electrolessly deposited contact layer.

6. The method of claim 1, further comprising heating the solar cell substrate to cause the contact layer to form a silicide, wherein the contact layer comprises nickel.

7. The method of claim 1, further comprising stripping the photoresist layer and then depositing the fill layer by plating.

8. The method of claim 7, further comprising annealing the solar cell substrate to generate a silicide prior to depositing the fill layer.

9. The method of claim 1, further comprising:
said electrolessly depositing a contact layer comprises depositing a nickel containing layer on the exposed silicon containing material; and
annealing the solar cell substrate to generate a nickel silicide.

10. The method of claim 1, further comprising depositing an oxidation protective coating on the fill layer.

11. The method of claim 1, further comprising illuminating the exposed silicon containing material while depositing the contact layer, wherein one or more wavelengths of light provided enhances the deposition of the contact layer.

12. The method of claim 1, wherein disposing the photoresist layer on the surface of the substrate comprises positioning a sheet of a photoresist material on the surface and applying heat and pressure to the photoresist material to cause the photoresist layer to bond to the surface.

13. The method of claim 1, further comprising cutting a buss wire 132 to a desired length and bonding the bus wire to a portion of the deposited fill layer.

14. A method of forming a solar cell device, comprising:
disposing a solar cell substrate on a carrier;
applying a composite assembly onto a surface of the solar cell substrate and a surface of the carrier, wherein the substrate is positioned in a space formed between the composite assembly and the carrier, and the composite assembly comprises a light sensitive material layer that is positioned over the surface of the substrate;
patterning the light sensitive material layer to form channels in the light sensitive material to expose one or more regions of the surface; and
depositing a contact layer on the surface of the substrate within the formed channels.

15. The method of claim 14, wherein depositing a contact layer comprises electrolessly depositing a layer on the exposed regions of the substrate disposed within the channels.

16. The method of claim 14, further comprising removing a portion of an antireflective coating within the channels prior to depositing the contact layer, wherein the antireflective coating is removed using a wet chemical solution that comprises a nickel ion, a silver ion or a tin ion.

17. The method of claim 14, further comprising disposing a metal containing paste within the channels, and heating the substrate to cause the metal within the metal containing paste to bond to the contact layer.

18. The method of claim 14, further comprising cutting a buss wire 132 to a desired length and bonding the bus wire to a portion of the deposited contact layer.

19. A method of forming a solar cell device, comprising:
applying a composite assembly onto a surface of the solar cell substrate, wherein the composite assembly comprises a light sensitive material layer that is positioned over the surface of the substrate;
patterning the light sensitive material layer to form channels in the light sensitive material to expose one or more regions of the surface;
removing material from the one or more regions of the surface so that a silicon containing material is exposed;
depositing a contact layer on the exposed silicon containing material to form an array of metal lines and two or more substantially transversely oriented buss bars on the front surface of a solar cell substrate; and
cutting a plurality of buss wires 132 to one or more desired lengths and bonding each of the plurality of bus wires to portion of the deposited contact layer.

20. The method of claim 19, further comprising forming a metal layer comprising silver on the contact layer before connecting each of the plurality of bus wires to the contact layer.

21. The method of claim 20, wherein the contact layer comprises between about 7 and about 15 substantially transversely oriented buss bars.

22. An assembly for forming a solar cell device, comprising:
a carrier having a surface;
a composite assembly comprising a light sensitive material layer; and
a first solar cell substrate disposed between the surface of the carrier and the composite assembly, wherein a first sealably enclosed space is formed by the carrier, the first solar cell substrate and the composite assembly.

23. The assembly of claim 22, wherein an electrical conductive layer disposed on the first solar cell substrate and within the first sealably enclosed space is coupled to a power source.

24. The assembly of claim 22, further comprising a second sealably enclosed space is formed by the carrier, a second solar cell substrate and the composite assembly.

25. The assembly of claim 22, wherein the light sensitive material layer has one or more channels formed therein so that one or more regions of the surface of the first solar cell substrate are exposed.
